(19) United States
(12) Patent Application Publication
(10) Pub. No.: US 2025/0022954 A1
(43) Pub. Date: Jan. 16, 2025

(54) SEMICONDUCTOR DEVICE

(71) Applicant: ROHM CO., LTD., Kyoto (JP)

(72) Inventor: Mitsuhide KORI, Kyoto (JP)

(73) Assignee: ROHM CO., LTD., Kyoto (JP)

(21) Appl. No.: 18/900,616

(22) Filed: Sep. 27, 2024

Related U.S. Application Data
(63) Continuation of application No. PCT/JP2023/009423, filed on Mar. 10, 2023.

(30) Foreign Application Priority Data
Mar. 30, 2022 (JP) 2022-055514

(51) Int. Cl. H01L 29/78; H01L 29/06; H01L 29/423

(52) U.S. Cl. CPC H01L 29/7816; H01L 29/0649; H01L 29/0692; H01L 29/42356

(57) ABSTRACT

A semiconductor device includes a chip having a principal surface, a trench insulating structure formed in the principal surface of the chip, a first conductivity type body region formed in a surface layer portion of the principal surface such that the body region is in contact with the trench insulating structure, a second conductivity type source region formed in a surface layer portion of the body region while being separated from the trench insulating structure, a first conductivity type butting region formed in a region between the trench insulating structure and the source region in the surface layer portion of the body region, and a planar gate structure that passes through a side of the butting region, covers the body region and the trench insulating structure, and is capable of controlling reversal and non-reversal of a channel in the body region.

### CROSS REFERENCE TO RELATED APPLICATIONS

The present application is a bypass continuation application of International Patent Application No.PCT/JP2023/009423, filed on Mar. 10, 2023, which corresponds to Japanese Patent Application No. 2022-055514 filed on Mar. 30, 2022 with the Japan Patent Office, and the entire disclosure of this application is incorporated herein by reference.

### TECHNICAL FIELD

The present disclosure relates to a semiconductor device.

### BACKGROUND ART

For example, Patent Literature 1 (Japanese Translation of International Application No. 2005-510080) discloses a method of restricting formation of a divot of a shallow trench isolation (STI) structure. The method of Patent Literature 1 includes a step of providing oxide deposited on a trench which is formed in a silicon region, a step of oxidizing an upper layer of the silicon region and forming a thermal oxide layer in an upper surface of the silicon region, and a step of selectively etching the oxide on which the thermal oxide is deposited.

### BRIEF DESCRIPTION OF DRAWINGS

FIG. 1 is a schematic plan view of a semiconductor device according to a preferred embodiment of the present disclosure.

FIG. 2 is an enlarged view of a region surrounded by a double chain line II in FIG. 1.

FIG. 3 is a cross-sectional view taken along line III-III in FIG. 2.

FIG. 4 is a cross-sectional view taken along line IV-IV in FIG. 2.

FIG. 5 is a cross-sectional view taken along line V-V in FIG. 2.

FIG. 6 is a cross-sectional view taken along line VI-VI in FIG. 2.

FIG. 7 is an enlarged view of a part surrounded by a double chain line VII in FIG. 6.

FIG. 8 is a graph illustrating relationships between gate voltages applied to Samples 1 and 2 and drain currents flowing through transistors of Samples 1 and 2.

### DESCRIPTION OF EMBODIMENTS

Next, a preferred embodiment of the present disclosure will be described in detail with reference to the attached drawings.

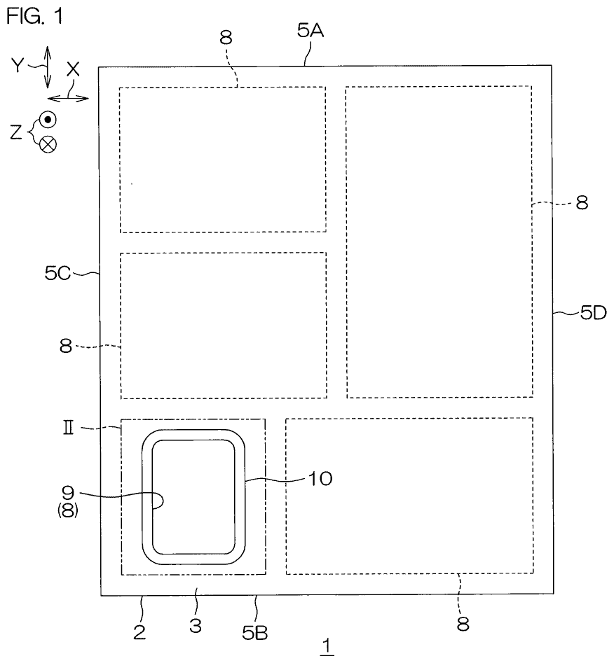

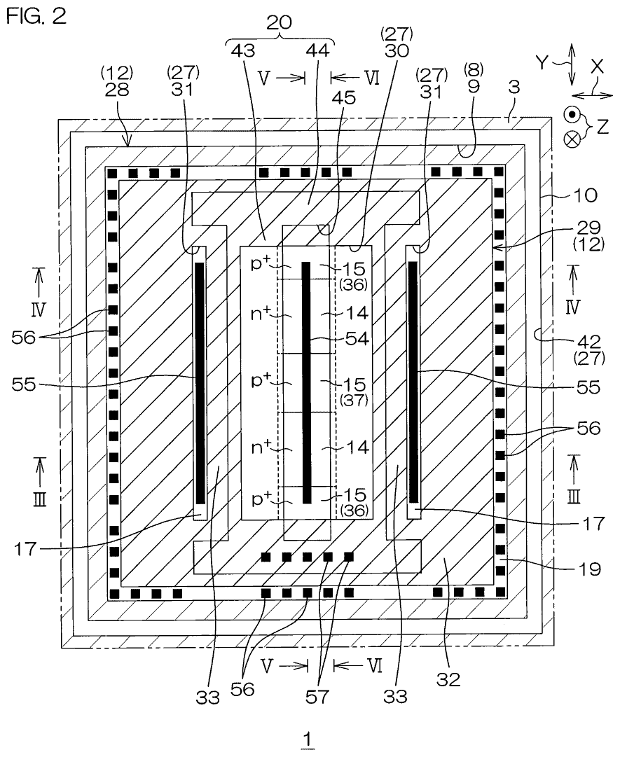

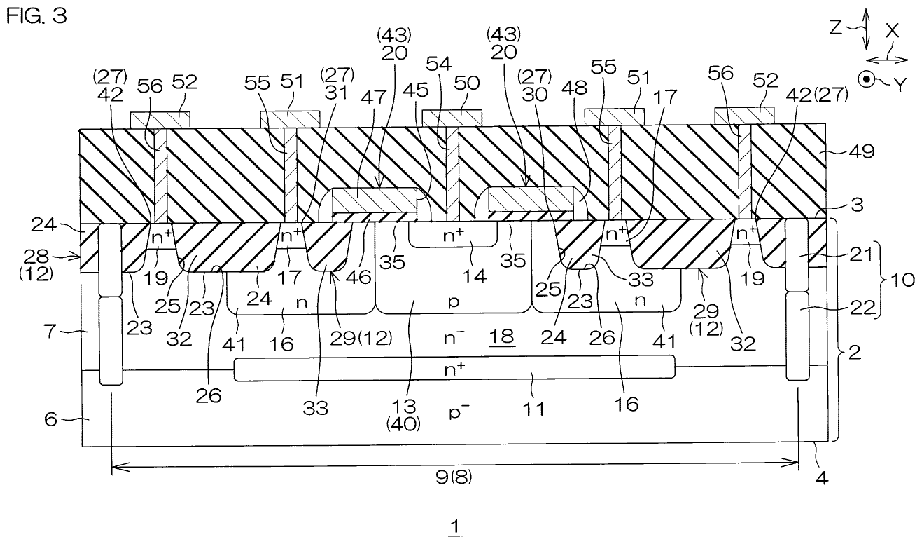

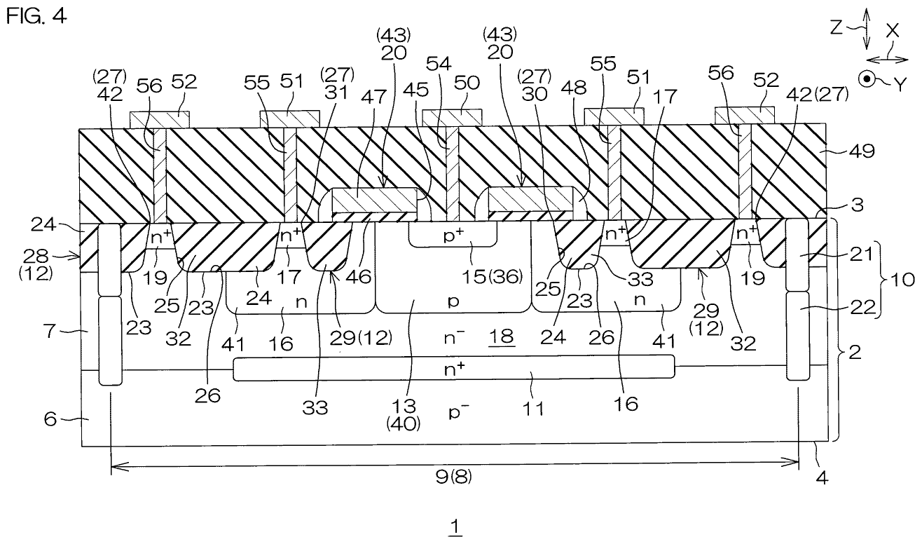

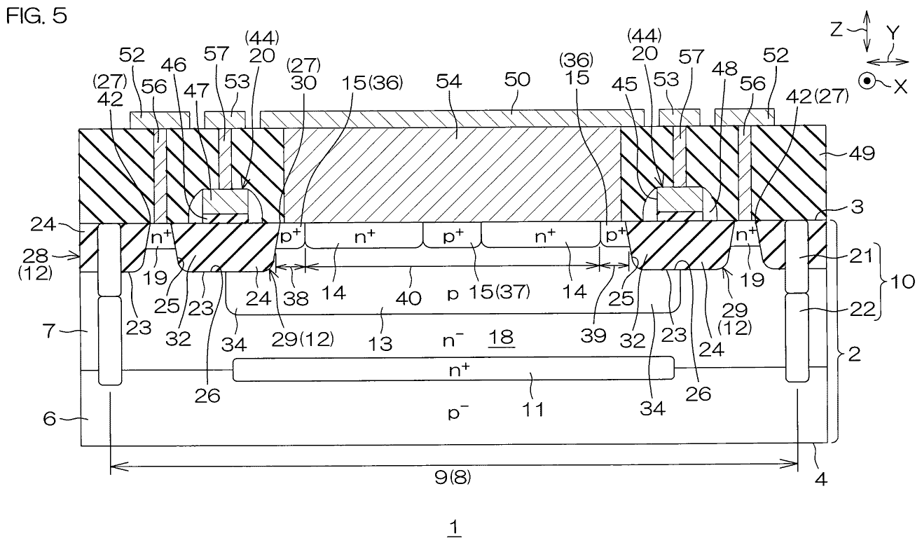

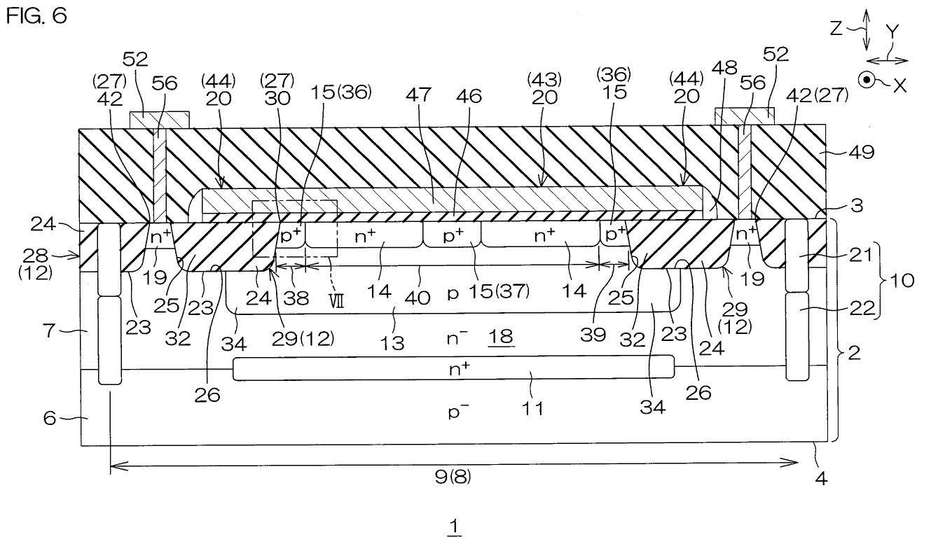

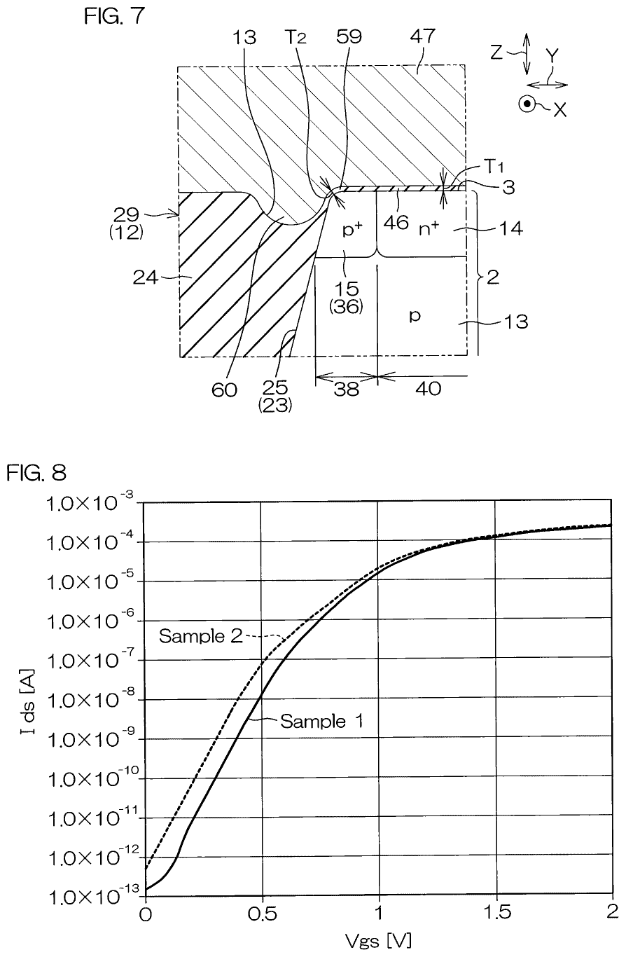

FIG. 1 is a schematic plan view of a semiconductor device 1 according to a preferred embodiment of the present disclosure. FIG. 2 is an enlarged view of a region surrounded by a double chain line II in FIG. 1. FIG. 3 is a cross-sectional view taken along line III-III in FIG. 2. FIG. 4 is a cross-sectional view taken along line IV-IV in FIG. 2. FIG. 5 is a cross-sectional view taken along line V-V in FIG. 2. FIG. 6 is a cross-sectional view taken along line VI-VI in FIG. 2. FIG. 7 is an enlarged view of a part surrounded by a double chain line VII in FIG. 6.

The semiconductor device 1 includes a rectangular-parallelepiped semiconductor chip 2. In this preferred embodiment, the semiconductor chip 2 is formed by an Si (silicon) chip. The semiconductor chip 2 has a first principal surface 3 on one side, a second principal surface 4 on the other side, and first to fourth side surfaces 5A to 5D that connect the first principal surface 3 and the second principal surface 4.

The first principal surface 3 and the second principal surface 4 are formed in a square shape in a plan view seen from the normal direction Z of the principal surfaces (hereinafter, simply referred to as “in a plan view”). The normal direction Z is also the thickness direction of the semiconductor chip 2. The first side surface 5A and the second side surface 5B extend in the first direction X (horizontal direction) along the first principal surface 3, and oppose each other in the second direction Y (horizontal direction) crossing (specifically, orthogonal to) the first direction X. The third side surface 5C and the fourth side surface 5D extend in the second direction Y and oppose each other in the first direction X.

The semiconductor device 1 includes a p-type region 6 (first conductivity type region) and an n-type region 7 (second conductivity type region) formed in the semiconductor chip 2.

The p-type region 6 is formed in a surface layer portion of the second principal surface 4 of the semiconductor chip 2. The p-type region 6 is formed over the entire surface layer portion of the second principal surface 4, and exposed from the second principal surface 4 and the first to fourth side surfaces 5A to 5D. A p-type impurity concentration of the p-type region 6 may be, for example, not less than 1.0×10¹³ cm⁻³ and not more than 1.0×10¹⁵ cm⁻³. A thickness of the p-type region 6 may be not less than 100 μm and not more than 500 μm. In this preferred embodiment, the p-type region 6 may be formed by a p-type semiconductor substrate. It is noted that since having a relatively low impurity concentration, the p-type region 6 may also be called as the p⁻-type region.

The n-type region 7 is formed in a surface layer portion of the first principal surface 3 of the semiconductor chip 2. In this preferred embodiment, the n-type region 7 is in direct contact with the p-type region 6. An n-type impurity concentration of the n-type region 7 may be, for example, not less than 1.0×10¹⁴ cm⁻³ and not more than 1.0×10¹⁶ cm⁻³. The n-type region 7 is formed over the entire surface layer portion of the first principal surface 3, and exposed from the first principal surface 3 and the first to fourth side surfaces 5A to 5D. A thickness of the n-type region 7 is, for example, smaller than the thickness of the p-type region 6. The thickness of the n-type region 7 may be not less than 5 μm and not more than 20 μm. In this preferred embodiment, the n-type region 7 may be formed by an n-type epitaxial layer. It is noted that since having a relatively low impurity concentration, the n-type region 7 may also be called as the n⁻-type region.

The semiconductor device 1 includes a plurality of element regions 8 provided in the first principal surface 3 (n-type region 7). The plurality of element regions 8 are regions in which various functional elements are respectively formed. The plurality of element regions 8 are respectively partitioned in an inner side portion of the first principal surface 3 at an interval from the first to fourth side surfaces 5A to 5D in a plan view. The number, arrangement, and shape of the element regions 8 are arbitrary, and are not limited to the particular number, arrangement, and shape.

The plurality of functional elements may respectively include at least one of a semiconductor switching element, a semiconductor rectifying element, and a passive element. The semiconductor switching element may include at least one of a junction field effect transistor (JFET), a metal insulator semiconductor field effect transistor (MISFET), a bipolar junction transistor (BJT), and an insulated gate bipolar junction transistor (IGBT).

The semiconductor rectifying element may include at least one of a pn-junction diode, a pin-junction diode, a Zener diode, a Schottky barrier diode, and a fast recovery diode. The passive element may include at least one of a resistance, a capacitor, an inductor, and a fuse. In this preferred embodiment, the plurality of element regions 8 include at least one transistor region 9. Hereinafter, a structure on the transistor region 9 side will be specifically described.

In the transistor region 9, the semiconductor device 1 may include an element separation portion 10, an embedded layer 11, a trench insulating structure 12, a body region 13, source regions 14, butting regions 15, a drift region 16, a drain region 17, a back gate region 18, a back gate contact region 19, and a planar gate structure 20.

The element separation portion 10 may include element separation wells 21, 22. More specifically, the p-type element separation wells 21, 22 formed in a band shape, the element separation wells that draw a closed curve in a plan view as illustrated in FIG. 2 may reach the p-type region 6 from the first principal surface 3 of the semiconductor chip 2. In this preferred embodiment, the element separation portion 10 is formed in a square ring shape in a plan view as illustrated in FIG. 2, but may have, for example, other closed curve structures of a circular ring shape, a triangular ring shape, etc.

The element separation portion 10 may have a double layer structure of a p⁺-type well region 21 disposed on the upper side, and a ⁻-type low isolation (L/I) region 22 disposed on the lower side. A border between these regions may be set in an intermediate portion in the thickness direction of the n-type region 7. For example, the border between the regions may be set at a depth position of 1.0 μm to 2.0 μm from the first principal surface 3 of the semiconductor chip 2. Thereby, in the semiconductor chip 2, the transistor region 9 formed by part of the n-type region 7 which is surrounded by the element separation portion 10 on the p-type region 6 is partitioned.

The n⁺-type embedded layer 11 (B/L) is selectively formed in the transistor region 9. With reference to FIGS. 3 to 6, the embedded layer 11 goes across a border between the p-type region 6 and the n-type region 7 in the semiconductor chip 2. A thickness of the embedded layer 11 may be, for example, 2.0 μm to 3.0 μm.

In this preferred embodiment, the trench insulating structure 12 includes a trench 23 formed in the n-type region 7, and an embedded insulating body 24 embedded in the trench 23.

The trench 23 has a side surface 25 and a bottom surface 26. The side surface 25 of the trench 23 may be a surface orthogonal to the first principal surface 3, or may be a surface inclined with respect to the first principal surface 3 as illustrated in FIGS. 3 to 6. The trench 23 may have a tapered shape whose width is gradually narrowed from the first principal surface 3 toward the bottom surface 26 in the third direction Z in a cross-sectional view.

The embedded insulating body 24 may be, for example, silicon oxide (SiO₂), silicon nitride (SiN), etc. In this preferred embodiment, the embedded insulating body 24 is made of silicon oxide. The embedded insulating body 24 exposes an opening end 27 of the trench 23. Also, the trench insulating structure 12 may also be called as a shallow trench isolation (STI) as a general name.

In this preferred embodiment, the trench insulating structure 12 may include a plurality of trench insulating structures 12. The plurality of trench insulating structures 12 may include a first trench insulating structure 28 and a second trench insulating structure 29. In FIG. 2, a region of the trench insulating structure 12 is hatched.

With reference to FIG. 2, the first trench insulating structure 28 is formed in an outer peripheral portion of the transistor region 9 such that the first trench insulating structure 28 overlaps with the element separation portion 10 in a plan view. In this preferred embodiment, the first trench insulating structure 28 is formed in a square ring shape in a plan view as illustrated in FIG. 2, but may have, for example, other closed curve structures of a circular ring shape, a triangular ring shape, etc.

The second trench insulating structure 29 is formed at an interval inward from an inner peripheral edge of the first trench insulating structure 28. The second trench insulating structure 29 is physically separated from the first trench insulating structure 28. With reference to FIG. 2, the second trench insulating structure 29 is surrounded by the first trench insulating structure 28. The second trench insulating structure 29 has a first opening 30 and a second opening 31. Inner peripheral edges of the first opening 30 and the second opening 31 may be the opening end 27 of the trench 23 described above.

With reference to FIG. 2, the first opening 30 is formed in a rectangular shape in a plan view elongated along the second direction Y. The second opening 31 includes a pair of second openings 31 that sandwich the first opening 30 in the first direction X. Each second opening 31 is formed in a rectangular shape in a plan view elongated along the second direction Y. The second trench insulating structure 29 includes a ring-shaped outer peripheral portion 32 that surrounds the first opening 30 and the second opening 31, and a coupling portion 33 that couples a plurality of points of the outer peripheral portion 32 and forms a border between the first opening 30 and the second opening 31. The coupling portion 33 includes a pair of coupling portions 33 formed on both the sides of the first opening 30 in the first direction X.

The body region 13 is formed in a surface layer portion of the n-type region 7 and electrically connected to the n-type region 7. The body region 13 is formed in an inner region of the first opening 30 at an interval from the second trench insulating structure 29. With reference to FIGS. 3 and 4, the body region 13 is physically separated inward from an inner peripheral edge of the first opening 30 in the first direction X. With reference to FIGS. 5 and 6, the body region 13 extends in the second direction Y, and is in contact with the second trench insulating structure 29 in both end portions of the first opening 30 in the second direction Y. With reference to FIGS. 5 and 6, the body region 13 has an overlap portion 34 that projects to the outer side of the inner peripheral edge of the first opening 30 and overlaps with the second trench insulating structure 29 in the second direction Y. The overlap portion 34 gets into under the second trench insulating structure 29, and is in contact with a bottom portion of the second trench insulating structure 29 (the bottom surface 26 of the trench 23). In this preferred embodiment, the body region 13 is a p-type semiconductor region. The body region 13 has an impurity concentration of 1×10¹⁷ cm⁻³ to 1×10¹⁸ cm⁻³, for example. Also, a depth of the body region 13 is deeper than a bottom portion position of the trench insulating structure 12, and may be, for example, 0.5 μm to 4.0 μm.

The source regions 14 and the butting regions 15 are formed in a surface layer portion of the body region 13 and electrically connected to the body region 13. Since the butting region 15 is a region of the same conductivity type as the body region 13, the region being connected to the body region 13, the butting region 15 may also be called as a body contact region. With reference to FIGS. 3 and 4, the source regions 14 and the butting regions 15 are physically separated inward from an outer peripheral edge of the body region 13 and formed in an inner region of the body region 13 in the first direction X. Regions sandwiched between the outer peripheral edge of the body region 13 and outer peripheral edges of the source regions 14 and configured by the body region 13 are channel regions 35 in which channels are formed when an appropriate voltage is applied to the planar gate structure 20.

With reference to FIGS. 2, 5, and 6, the plurality of source regions 14 and the plurality of butting regions 15 are formed alternately along the second direction Y. The source region 14 and the butting region 15 adjacent to each other are in contact with each other. In this preferred embodiment, the butting regions 15 are formed in regions between the second trench insulating structure 29 and the source regions 14 in the second direction Y. More specifically, the butting regions 15 include first butting regions 36 and a second butting region 37.

The first butting regions 36 are formed on the outer side of the source regions 14 and sandwiched between the outer peripheral portion 32 of the second trench insulating structure 29 and the source regions 14 in the second direction Y. Thereby, the first butting regions 36 are in contact with the second trench insulating structure 29. In this preferred embodiment, the first butting regions 36 are formed one by one in each of both the end portions of the first opening 30 (a first end portion 38 and a second end portion 39 of the body region 13) in the second direction Y, and cover the opening end 27 of the trench 23 from the side. Since the first butting regions 36 are formed on the outer side of the source regions 14, the first butting regions 36 may also be called as outside butting regions. With reference to FIG. 2, the first butting regions 36 are formed in a square shape in a plan view.

The second butting region 37 is sandwiched by the pair of source regions 14 in the second direction Y. In this preferred embodiment, only one second butting region 37 is formed in a central portion 40 of the body region 13 in the second direction Y. However, a plurality of second butting regions 37 may be formed. Since the second butting region 37 is formed on the inner side of the source regions 14, the second butting region 37 may also be called as an inside butting region. With reference to FIG. 2, the second butting region 37 is formed in a square shape in a plan view. The second butting region 37 has a planar area larger than the first butting regions 36.

The source regions 14 are formed in regions of the body region 13 exposed from the first opening 30, the regions excluding the butting regions 15. The source region 14 is formed between the pair of adjacent butting regions 15 and sandwiched between the pair of butting regions 15 in the second direction Y. In this preferred embodiment, the source regions 14 are n⁺-type semiconductor regions. The source regions 14 have an impurity concentration of 1×10¹⁹ cm⁻³ to 5×10²¹ cm⁻³, for example. Also, a depth of the source regions 14 is shallower than the body region 13 and the trench insulating structure 12, and may be, for example, 0.2 μm to 1.0 μm. Therefore, in a cross-sectional view, side portions and bottom portions of the source regions 14 are integrally covered by the body region 13 in the first direction X (see FIG. 3).

In this preferred embodiment, the butting regions 15 are p⁺-type semiconductor regions and have an impurity concentration higher than the body region 13. The butting regions 15 have an impurity concentration of 1×10¹⁹ cm⁻³ to 5×10²¹ cm⁻³, for example. Also, a depth of the butting regions 15 is shallower than the body region 13 and the trench insulating structure 12, and may be, for example, 0.2 μm to 1.0 μm. Therefore, in a cross-sectional view, side portions and bottom portions of the butting regions 15 are integrally covered by the body region 13 in the first direction X (see FIG. 4).

The drift region 16 is formed in the surface layer portion of the n-type region 7 and electrically connected to the n-type region 7. The drift region 16 goes across the first opening 30 and the second opening 31 of the second trench insulating structure 29, and exposed from both the first opening 30 and the second opening 31. The drift region 16 extends along the body region 13 in the second direction Y, and is in contact with the second trench insulating structure 29 in both the end portions of the first opening 30 in the second direction Y. Also, the drift region 16 may be in contact with the body region 13 in the second opening 31.

With reference to FIGS. 3 and 4, the drift region 16 has an overlap portion 41 that projects to the outer side of an inner peripheral edge of the second opening 31 and overlaps with the second trench insulating structure 29 in the first direction X. The overlap portion 41 gets into under the second trench insulating structure 29, and is in contact with the bottom portion of the second trench insulating structure 29 (the bottom surface 26 of the trench 23). In this preferred embodiment, the drift region 16 is an n-type semiconductor region and has an impurity concentration higher than the n-type region 7. The drift region 16 has an impurity concentration of 1×10¹⁷ cm⁻³ to 1×10¹⁸ cm⁻³, for example. Also, a depth of the drift region 16 is deeper than the bottom portion position of the trench insulating structure 12, and may be, for example, 0.5 μm to 4.0 μm.

The drain region 17 is formed in a surface layer portion of the drift region 16 and electrically connected to the drift region 16. The drain region 17 is separated from the body region 13 in the first direction X and exposed from the second opening 31 of the second trench insulating structure 29. The drain region 17 is formed in a rectangular shape in a plan view extending along the longitudinal direction of the second opening 31. The drain region 17 may include a pair of drain regions 17 that oppose each other across the source regions 14 in the first direction X. In this preferred embodiment, the drain region 17 is an n⁺-type semiconductor region and has an impurity concentration higher than the drift region 16. The drain region 17 has an impurity concentration of 1×10¹⁹ cm⁻³ to 5×10²¹ cm⁻³, for example. Also, a depth of the drain region 17 may be, for example, 0.2 μm to 2.0 μm. For example, the drain region 17 may have the same depth as the source regions 14.

The back gate region 18 is a region formed by the n-type region 7 in the transistor region 9. The back gate region 18 is exposed from a third opening 42 between the first trench insulating structure 28 and the second trench insulating structure 29. The back gate region 18 has an exposed part that surrounds the second trench insulating structure 29.

The back gate contact region 19 is formed in a surface layer portion of the back gate region 18 and electrically connected to the back gate region 18. The back gate contact region 19 is separated from the body region 13 and the drift region 16 and exposed from the third opening 42. The back gate contact region 19 is formed in a square ring shape in a plan view extending along the third opening 42. In this preferred embodiment, the back gate region 18 is an n⁺-type semiconductor region and has an impurity concentration higher than the n-type region 7. The back gate region 18 has an impurity concentration of 1×10¹⁹ cm⁻³ to 5×10²¹ cm⁻³, for example. Also, a depth of the back gate region 18 may be, for example, 0.2 μm to 2.0 μm. For example, the back gate region 18 may have the same depth as the source regions 14 and the drain region 17.

The planar gate structure 20 is formed on the first principal surface 3 and covers the channel regions 35. The planar gate structure 20 integrally includes a main body portion 43 that controls ON/OFF of the channel regions 35, and contact portions 44 that receive supply of a voltage.

With reference to FIGS. 2 to 4, the main body portion 43 includes a pair of main body portions 43 that oppose the pair of channel regions 35 formed on both the sides of the source regions 14 in the first direction X. The pair of main body portions 43 extend across a plurality of borders between the source regions 14 and the butting regions 15 along the second direction Y. The pair of main body portions 43 are parallel to each other along the second direction Y. The pair of main body portions 43 cover both end portions of the source regions 14 and the butting regions 15 in the first direction X. The pair of main body portions 43 are formed in a rectangular shape in a plan view elongated along the second direction Y and have both end portions on the second trench insulating structure 29.

The contact portions 44 are formed on the second trench insulating structure 29 and connected to the main body portion 43 on the second trench insulating structure 29. Each one of the contact portions 44 is formed in both longitudinal end portions of the pair of main body portions 43. The contact portions 44 are formed in a rectangular shape in a plan view elongated along the direction going across the pair of main body portions 43 (direction along the first direction X). Thereby, the planar gate structure 20 is formed in a substantially square ring shape in a plan view as illustrated in FIG. 2, and has a gate opening 45 in a central portion thereof. The gate opening 45 is formed in a rectangular shape in a plan view, and the butting regions 15 and the source regions 14 are alternately exposed along the longitudinal direction thereof. Both longitudinal ends of the gate opening 45 are formed on the second trench insulating structure 29.

The planar gate structure 20 includes a gate insulating film 46 and a gate electrode 47 laminated in this order from the first principal surface 3 side. The gate insulating film 46 may include a silicon oxide film. The gate insulating film 46 preferably includes a silicon oxide film made of oxide of the semiconductor chip 2. The gate electrode 47 preferably includes conductive polysilicon. The gate electrode 47 preferably includes conductive polysilicon to which an impurity is introduced. The gate electrode 47 may have a conductivity type of a p-type or may have a conductivity type of an n-type. A side wall 48 is formed in a periphery of the gate electrode 47. The side wall 48 is continuously formed over the entire periphery of the gate electrode 47 and covers a side surface of the gate electrode 47. The side wall 48 may be, for example, silicon oxide (SiO₂), silicon nitride (SiN), etc.

With reference to FIGS. 3 to 6, an interlayer insulating film 49 is formed on the first principal surface 3 and covers the planar gate structure 20. The interlayer insulating film 49 is made of silicon oxide, for example. A plurality of wirings 50 to 53 are formed on the interlayer insulating film 49. The plurality of wirings 50 to 53 may include a source wiring 50, a drain wiring 51, a back gate wiring 52, and a gate wiring 53, respectively.

The source wiring 50 is connected to the source regions 14 and the butting regions 15 via a source contact 54 embedded in the interlayer insulating film 49. With reference to FIG. 2, the source contact 54 may be formed in a rectangular shape in a plan view extending along the longitudinal direction of the first opening 30. The source contact 54 goes across the borders between the source regions 14 and the butting regions 15 in the second direction Y and is collectively connected to the source regions 14 and the butting regions 15.

The drain wiring 51 is connected to the drain region 17 via a drain contact 55 embedded in the interlayer insulating film 49. With reference to FIG. 2, the drain contact 55 may be formed in a rectangular shape in a plan view extending along the longitudinal direction of the second opening 31.

The back gate wiring 52 is connected to the back gate contact region 19 via back gate contacts 56 embedded in the interlayer insulating film 49. With reference to FIG. 2, the plurality of back gate contacts 56 are disposed at intervals along the circumferential direction of the third opening 42.

The gate wiring 53 is connected to the gate electrode 47 (contact portion 44) via gate contacts 57 embedded in the interlayer insulating film 49. With reference to FIG. 2, the plurality of gate contacts 57 are disposed at intervals along the longitudinal direction of the contact portion 44.

With reference to FIG. 7, a cross-sectional structure of the first end portion 38 and the second end portion 39 in the second direction Y of the body region 13 will be described in detail. Although FIG. 7 illustrates a structure in the first end portion 38 among the first end portion 38 and the second end portion 39 of the body region 13 as an example, the structure of the first end portion 38 can also be applied to the second end portion 39. A dent 58 is selectively formed in the embedded insulating body 24 of the second trench insulating structure 29 in the vicinity of the first end portion 38 of the body region 13. The dent 58 is a dent 58 generated due to cleaning processing (such as light etching with a hydrofluoric acid solution), etc., performed each time before a thermal oxidation process for forming the gate insulating film 46, and may also be called as a divot. This dent 58 may be continuously formed over the entire periphery of the body region 13 such that the dent 58 surrounds the body region 13.

The gate insulating film 46 covers the opening end 27 of the trench 23 such that the gate insulating film 46 is connected to the embedded insulating body 24 in this dent 58. The gate electrode 47 covers the dent 58 of the embedded insulating body 24 and may include an embedded portion 60 embedded in the dent 58. In a part of the dent 58, a remarkable thin film portion 59 is generated in the gate insulating film 46. For example, a thickness T₁ of the gate insulating film 46 in the central portion 40 in the second direction Y of the body region 13 (part between the first end portion 38 and the second end portion 39) is not less than 50 Å and not more than 250 Å, and a thickness T₂ of the thin film portion 59 is smaller than the thickness T₁ of the central portion 40. This thin film portion 59 becomes a cause of leakage, and invites a decrease in a withstand voltage of the gate insulating film 46. Also, since this thin film portion 59 partially forms a region of a low threshold value, the thin film portion 59 invites deterioration of static characteristics (such as instability of a threshold value) of a transistor.

Therefore, in this preferred embodiment, a structure in which the deterioration of the static characteristics is not generated is provided. More specifically, the butting regions 15 are formed in end cap parts of the body region 13 (in this preferred embodiment, the first end portion 38 and the second end portion 39). The butting regions 15 are regions that ensure conduction with respect to the body region 13 and do not relate to transistor actions. Therefore, at the time of applying a gate voltage, it is possible to suppress formation of channels in the first end portion 38 and the second end portion 39 of the body region 13 in contact with the thin film portion 59 of the gate insulating film 46, and preferentially and stably form a channel in the central portion 40 of the body region 13. As a result, it is possible to suppress a hump phenomenon from generating in a drain current-gate voltage (Ids-Vgs) characteristic.

For example, the graph of FIG. 8 is a graph respectively illustrating relationships between gate voltages applied to Samples 1 and 2 and drain currents flowing through transistors of Samples 1 and 2. Sample 1 is the semiconductor device 1 according to this preferred embodiment, and Sample 2 is a semiconductor device 1 in which the first butting regions 36 are not disposed in the semiconductor device 1. From comparison between the graph of Sample 1 and the graph of Sample 2, it is found that a hump waveform is suppressed in Sample 1.

Although the preferred embodiment of the present disclosure has been described, the present disclosure can also be implemented in other preferred embodiments.

For example, the example in which the first conductivity type is the p-type and the second conductivity type is the n-type is described in the preferred embodiment described above. However, the first conductivity type may be the n-type and the second conductivity type may be the p-type. A specific arrangement of this case can be obtained by replacing the n-type regions with the p-type regions and replacing the p-type regions with the n-type regions in the above description and the attached drawings. In the preferred embodiment described above, the example in which the p-type is expressed as the “first conductivity type” and the n-type is expressed as the “second conductivity type” is described. However, these are used for clarifying the order of description. The p-type may be expressed as the “second conductivity type,” and the n-type may be expressed as the “first conductivity type.”

As described above, the preferred embodiments of the present disclosure are examples in all points, should not be interpreted in a limited manner, and intend to include changes in all points.

The following appended features can be extracted from the descriptions in this Description and the drawings.

### Appendix 1-1

A semiconductor device, including a chip having a principal surface, a trench insulating structure formed in the principal surface of the chip, a first conductivity type body region formed in a surface layer portion of the principal surface such that the body region is in contact with the trench insulating structure, a second conductivity type source region formed in a surface layer portion of the body region while being separated from the trench insulating structure, a first conductivity type butting region formed in a region between the trench insulating structure and the source region in the surface layer portion of the body region, and a planar gate structure that passes through a side of the butting region, covers the body region and the trench insulating structure, and is capable of controlling reversal and non-reversal of a channel in the body region.

### Appendix 1-2

The semiconductor device according to Appendix 1-1, wherein the butting region has an impurity concentration higher than the body region.

### Appendix 1-3

The semiconductor device according to Appendix 1-1 or 1-2, wherein the butting region is formed in the surface layer portion of the body region such that the butting region is in contact with the trench insulating structure.

### Appendix 1-4

The semiconductor device according to any one of Appendices 1-1 to 1-3, wherein the planar gate structure has a part that covers the butting region.

### Appendix 1-5

The semiconductor device according to any one of Appendices 1-1 to 1-4, further including at least one first conductivity type inside butting region formed in the surface layer portion of the body region while being separated from the trench insulating structure.

### Appendix 1-6

The semiconductor device according to Appendix 1-5, wherein a planar area of the inside butting region is larger than a planar area of the butting region.

### Appendix 1-7

The semiconductor device according to any one of Appendices 1-1 to 1-6, wherein the trench insulating structure includes a trench formed in the principal surface, and an insulating body embedded in the principal surface such that the insulating body exposes an opening end of the trench, and the planar gate structure includes a gate insulating film that covers the body region and the opening end, and a gate electrode that opposes the body region and the opening end across the gate insulating film.

### Appendix 1-8

The semiconductor device according to Appendix 1-7, wherein the trench insulating structure has a divot dented toward a bottom wall of the trench so that the opening end of the trench is exposed in an upper end portion of the insulating body, and the gate insulating film covers the opening end such that the gate insulating film is connected to the insulating body in the divot.

### Appendix 1-9

The semiconductor device according to Appendix 1-7 or 1-8, wherein the butting region covers the opening end in the body region.

### Appendix 1-10

The semiconductor device according to any one of Appendices 1-1 to 1-9, further including a second conductivity type drain region formed in the surface layer portion of the principal surface while being separated from the body region.

### Appendix 1-11

The semiconductor device according to Appendix 1-10, further including a second conductivity type drift region formed in a region different from the body region in the surface layer portion of the principal surface, wherein the drain region is formed in a surface layer portion of the drift region.

### Appendix 1-12

The semiconductor device according to Appendix 1-11, wherein the drain region has an impurity concentration higher than the drift region.

What is claimed is:

1. A semiconductor device, comprising:
a chip having a principal surface;
a trench insulating structure formed in the principal surface of the chip;
a first conductivity type body region formed in a surface layer portion of the principal surface such that the body region is in contact with the trench insulating structure;
a second conductivity type source region formed in a surface layer portion of the body region while being separated from the trench insulating structure;
a first conductivity type butting region formed in a region between the trench insulating structure and the source region in the surface layer portion of the body region; and
a planar gate structure that passes through a side of the butting region, covers the body region and the trench insulating structure, and is capable of controlling reversal and non-reversal of a channel in the body region.

2. The semiconductor device according to claim 1, wherein
the butting region has an impurity concentration higher than the body region.

3. The semiconductor device according to claim 1, wherein
the butting region is formed in the surface layer portion of the body region such that the butting region is in contact with the trench insulating structure.

4. The semiconductor device according to claim 1, wherein
the planar gate structure has a part that covers the butting region.

5. The semiconductor device according to claim 1, further comprising:
at least one first conductivity type inside butting region formed in the surface layer portion of the body region while being separated from the trench insulating structure.

6. The semiconductor device according to claim 5, wherein
a planar area of the inside butting region is larger than a planar area of the butting region.

7. The semiconductor device according to claim 1, wherein
the trench insulating structure includes a trench formed in the principal surface, and an insulating body embedded in the principal surface such that the insulating body exposes an opening end of the trench, and
the planar gate structure includes a gate insulating film that covers the body region and the opening end, and a gate electrode that opposes the body region and the opening end across the gate insulating film.

8. The semiconductor device according to claim 7, wherein
the trench insulating structure has a divot dented toward a bottom wall of the trench so that the opening end of the trench is exposed in an upper end portion of the insulating body, and
the gate insulating film covers the opening end such that the gate insulating film is connected to the insulating body in the divot.

9. The semiconductor device according to claim 7, wherein
the butting region covers the opening end in the body region.

10. The semiconductor device according to claim 1, further comprising:
a second conductivity type drain region formed in the surface layer portion of the principal surface while being separated from the body region.

11. The semiconductor device according to claim 10, further comprising:
a second conductivity type drift region formed in a region different from the body region in the surface layer portion of the principal surface, wherein
the drain region is formed in a surface layer portion of the drift region.

12. The semiconductor device according to claim 11, wherein
the drain region has an impurity concentration higher than the drift region.
